(19) United States
(12) Patent Application Publication
(10) Pub. No.: US 2025/0040405 A1
(43) Pub. Date: Jan. 30, 2025

(54) DISPLAY DEVICE AND MANUFACTURING METHOD THEREOF

(71) Applicant: Samsung Display Co., Ltd., Yongin-si (KR)

(72) Inventor: In Tae SON, Yongin-si (KR)

(21) Appl. No.: 18/619,702

(22) Filed: Mar. 28, 2024

(30) Foreign Application Priority Data
Jul. 28, 2023 (KR) 10-2023-0099095

(51) Int. Cl. H10K 59/80; H10K 59/12

(52) U.S. Cl. CPC H10K 59/873; H10K 59/1201

(57) ABSTRACT

An embodiment provides a display device including: a display module including a display area; a window including a front area; curved areas bent with a curvature from the front area; and an edge area connecting one of the curved areas to another of the curved areas; and an adhesive layer disposed between the display module and the window. A filling member is disposed on the edge area, and a volume of the filling member is greater than a volume of air bubbles formed between the edge area and the adhesive layer when the display module and the window are combined.

### CROSS-REFERENCE TO RELATED APPLICATION

This application claims priority to and the benefit of Korean Patent Application No. 10-2023-0099095 filed in the Korean Intellectual Property Office on Jul. 28, 2023, the entire contents of which are incorporated herein by reference.

### BACKGROUND

### (A) Field

The present disclosure relates to an electronic device, and more particularly, to a display device and a manufacturing method thereof.

### (B) Description of the Related Art

Recently, as the number of consumers who value the design and ease of use of electronic devices increases, the designs of electronic devices are becoming increasingly diverse. Accordingly, the design of display devices is also becoming more diverse. For example, the display device may include a curved portion in which both sides are bent or curved.

The above information disclosed in this Background section is only for enhancement of understanding of the background of the inventive concepts, and, therefore, it may contain information that does not form the prior art that is already known to a person of ordinary skill in the art.

### SUMMARY

A feature of the present disclosure is to provide a display device with improved visibility.

Another feature of the present disclosure is to provide a manufacturing method of the display device.

An embodiment of the present disclosure provides a display device including: a display module including a display area; a window including: a front area; curved areas bent with a curvature from the front area; and an adhesive layer disposed between the display module and the window. A filling member is disposed on the edge area. A volume of the filling member is greater than a volume of air bubbles formed between the edge area and the adhesive layer when the display module and the window are combined.

The volume of the filling member may be 100 times or more than the volume of the air bubbles.

The filling member may be cured before the window and the display module are combined.

A refractive index of the filling member may be substantially the same as a refractive index of the adhesive layer.

The filling member may include an optically clear resin.

The adhesive layer may include an optically clear adhesive.

An embodiment of the present disclosure provides a display device including: a display module including a display area; and a window including: a front area; curved areas bent with a curvature from the front area; and an edge area connecting one of the curved areas to another of the curved areas. An adhesive layer is disposed between the display module and the window. The adhesive layer may include a filling area in contact with the edge area. A filling member is disposed on the filling area when the display module and the window are combined. A volume of the filling member may be greater than a volume of air bubbles formed between the edge area and the adhesive layer when the display module and the window are combined.

The volume of the filling member may be 100 times or more than the volume of the air bubbles.

The filling member may be cured before the window and the display module are combined.

A refractive index of the filling member may be substantially the same as a refractive index of the adhesive layer.

The filling member may include an optically clear resin, and the adhesive layer may include an optically clear adhesive.

An embodiment of the present disclosure provides a manufacturing method of a display device including a display module and a window. The manufacturing method of the display device includes: disposing a filling member on an edge area that connects one of curved areas included in the window to another of the curved areas; curing the filling member; and combining the display module and the window through an adhesive layer. A volume of the filling member may be greater than a volume of air bubbles formed between the edge area and the adhesive layer when the display module and the window are combined.

The manufacturing method may include removing the air bubbles by disposing the display device in an autoclave.

The volume of the filling member may be 100 times or more than the volume of the air bubbles.

The filling member may be cured before the window and the display module are combined.

A refractive index of the filling member may be substantially the same as a refractive index of the adhesive layer.

The filling member may include an optically clear resin, and the adhesive layer may include an optically clear adhesive.

The filling member may be disposed on the edge area by an ink-jet method.

The display device and the manufacturing method thereof according to the embodiments of the present disclosure may quickly manufacture a display device capable of outputting an image with improved visibility. For example, the display device may use a filling member to prevent the risk of air bubbles occurring in a display module. Accordingly, for example, a time required for a process of removing air bubbles is shortened, so that it is possible to quickly manufacture a display device that provides images with improved visibility.

Effects of embodiments of the present disclosure are not limited by what is illustrated in the above, and more various effects are included in the present specification.

### BRIEF DESCRIPTION OF THE DRAWINGS

FIG. 1 illustrates a perspective view of a display device according to an embodiment.

FIG. 2 illustrates an exploded perspective view of some components of a display device according to an embodiment of the present disclosure.

FIG. 3 illustrates a top plan view of an example of a pixel array included in a display area of FIG. 2.

FIG. 4 illustrates a top plan view of an example of a window shown in FIG. 2.

FIG. 5 illustrates a top plan view of an example in which a filling member is disposed on a window shown in FIG. 2.

FIG. 6 and FIG. 7 illustrate some of a manufacturing method of a display device according to an embodiment of the present disclosure.

FIG. 8 illustrates a top plan view of another example of an adhesive layer similar to an adhesive layer shown in FIG. 2.

FIG. 9 illustrates a top plan view of another example in which a filling member is disposed on the adhesive layer shown in FIG. 8.

FIG. 10 and FIG. 11 illustrate some of a manufacturing method of a display device according to an embodiment of the present disclosure.

FIG. 12 illustrates a flowchart of a manufacturing method of a display device according to an embodiment of the present disclosure.

FIG. 13 illustrates a flowchart of a manufacturing method of a display device according to an embodiment of the present disclosure.

### DETAILED DESCRIPTION OF THE EMBODIMENTS

Hereinafter, example embodiments of the present disclosure will be described in detail with reference to the accompanying drawings. The following description is intended to provide only a sufficient disclosure to enable the understanding of the operation of the inventive concept, and any other disclosure is omitted to avoid obscuring the scope of the inventive concept. In addition, the inventive concept may be embodied in different forms and is not limited to the embodiments set forth herein. The embodiments described herein are provided for the purpose of describing the technical concept of the inventive concept in sufficient detail for those skilled in the art to easily practice it.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the inventive concept. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another constituent element. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

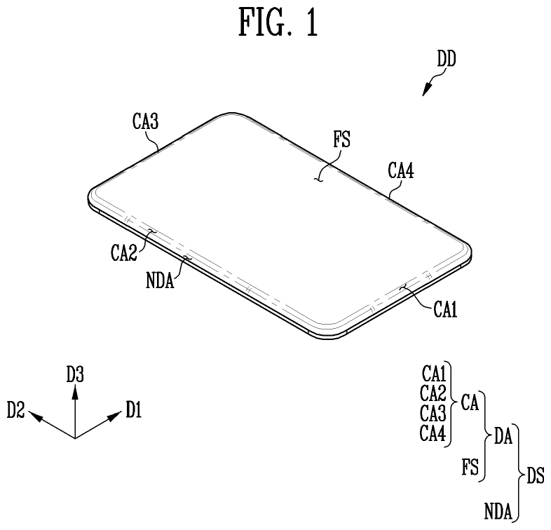

FIG. 1 illustrates a perspective view of a display device DD according to an embodiment.

Referring to FIG. 1, a display device DD may be a device that is activated according to an electrical signal. For example, the display device DD may be a mobile phone, tablet, car navigation system, game console, or wearable device. In addition, the display device DD may be an organic light emitting display device or a quantum dot light emitting display device, but is not limited thereto.

The display device DD may include a display surface DS defined by a first direction D1 and a second direction D2 that crosses the first direction D1. The display device DD may provide images to a user through the display surface DS.

The display surface DS may include a display area DA and a non-display area NDA around the display area DA. The display area DA may display an image, and the non-display area NDA may not display an image. The non-display area NDA may surround the display area DA. However, it is not limited thereto, and the shape of the display area DA and the shape of the non-display area NDA may be modified.

The display surface DS may include a front area FS and curved areas CA including first to fourth curved areas CA1 to CA4. In addition, the front area FS and the curved areas CA may be adjacent to each other to implement a continuous display area DA. For example, the front area FS and the first to fourth curved areas CA1 to CA4 may be adjacent to each other to implement a continuous display area DA.

The front area FS may be substantially parallel to a plane defined by the first direction D1 and the second direction D2. In some embodiments, the front area FS may have a concave or convex curved shape with respect to the plane defined by the first direction D1 and the second direction D2.

The curved areas CA may be bent from the front area FS. For example, the first to fourth curved areas CA1 to CA4 may be bent from the front area FS in an opposite direction of a third direction D3. Each of the first to fourth curved areas CA1 to CA4 may be bent from the front area FS to have a predetermined curvature. The curvatures of the first to fourth curved areas CA1 to CA4 may be the same or different from each other.

The first curved area CA1 and the third curved area CA3 each extend along the first direction D1, and may be spaced apart from each other in the second direction D2 with the front area FS therebetween. The second curved area CA2 and the fourth curved area CA4 each extend along the second direction D2, and may be spaced apart from each other in the first direction D1 with the front area FS therebetween.

In FIG. 1, it has been described as an example that the display device DD includes one front area FS and four curved areas CA, but the present disclosure is not limited thereto.

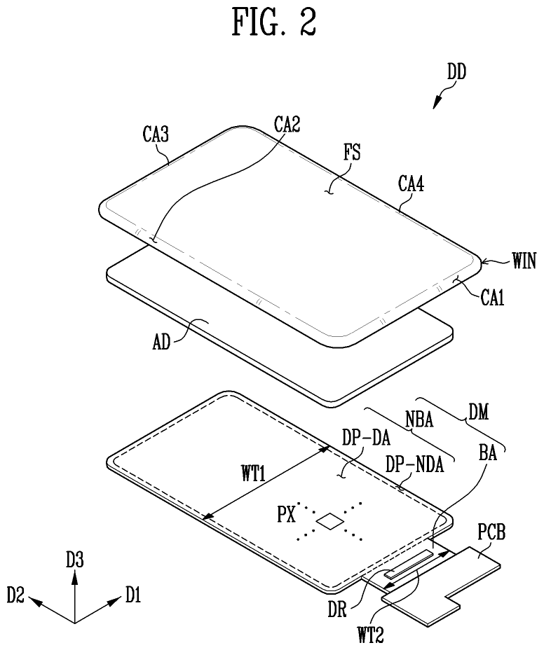

FIG. 2 illustrates an exploded perspective view of some components of a display device DD according to an embodiment of the present disclosure.

Referring to FIG. 2, the display device DD may include a window WIN, an adhesive layer AD, a display module DM, a driving chip DR, and a main circuit board PCB.

The display module DM may be disposed under the adhesive layer AD. The display module DM may include a non-bending area NBA and a bending area BA. The non-bending area NBA and the bending area BA may be adjacent in the second direction D2. The bending area BA may be a portion that protrudes and extends from the non-bending area NBA in a direction parallel to the second direction D2, and the bending area BA and the non-bending area NBA may have a continuous shape (or an integrated shape). A width WT1 of the non-bending area NBA in the first direction D1 may be larger than a width WT2 of the bending area BA in the first direction D1.

In some embodiments, the bending area BA may be bent toward a back surface of the non-bending area NBA. In the bending area BA, the driving chip DR may be mounted, and the main circuit board PCB may be attached. The driving chip DR may be a chip-type timing control circuit. However, this is an example, and the driving chip DR may be mounted on a separate film from the display module DM. In this case, the driving chip DR may be electrically connected to the display module DM through the film.

The non-bending area NBA of the display module DM may include a display area DP-DA and a non-display area DP-NDA. The non-display area DP-NDA may surround the display area DP-DA. The display area DP-DA and the non-display area DP-NDA of the display module DM may overlap the display area DA and the non-display area NDA of the window WIN. The display area DP-DA may provide an image toward the window WIN.

In some embodiments, the display device DD may further include a protection member disposed below the display module DM. The protection member may disposed below the display module DM to protect the display module DM from external impact. The protection member may include a plurality of layers. For example, the protection member may include a light blocking layer, a heat dissipating layer, a cushioning layer, and a plurality of adhesive layers.

The front of the window WIN defines the display surface DS (see FIG. 1) of the display device DD. In addition, the window WIN protects an upper surface of the display module DM.

The window WIN may include an optically transparent insulating material. For example, the window WIN may include glass or plastic. In addition, the window WIN may have a multi-layered structure or a single-layered structure. For example, the window WIN may include a plurality of plastic films bonded with an adhesive, or may include a glass substrate and a plastic film bonded with an adhesive.

The window WIN may include a front area FS and curved areas CA that are bent and extended from the front area FS. For example, the window WIN may include a front area FS and first to fourth curved areas CA1 to CA4 that are bent and extended from the front area FS.

The window WIN may be combined with the display module DM. For example, the window WIN may be combined to cover the non-bending area NBA of the display module DM.

The adhesive layer AD may be disposed between the display module DM and the window WIN. For example, the adhesive layer AD may be disposed on the display module DM to combine the window WIN and the display module DM.

The adhesive layer AD may be a transparent adhesive member such as a pressure sensitive adhesive film (PSA) or an optically clear adhesive film (OCA), but is not limited thereto.

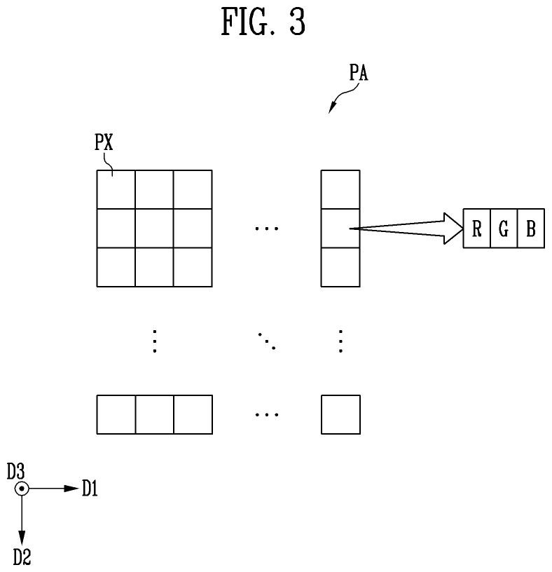

FIG. 3 illustrates a top plan view of an example of a pixel array PA included in a display area of FIG. 2.

Referring to FIG. 3, the pixel array PA may include a plurality of pixels PX arranged in the first and second directions D1 and D2. The pixels PX arranged along the first direction D1 among the plurality of pixels PX may form a pixel row, and the pixels PX arranged along the second direction D2 among the plurality of pixels PX may form a pixel column. Each of the plurality of pixels PX may include a plurality of sub-pixels. For example, each of the plurality of pixels PX may include a first pixel R configured to emit red color light, a second pixel G configured to emit green color light, and a third pixel B configured to emit blue color light.

Each of the plurality of pixels PX may include a light emitting element and a pixel circuit configured to drive the light emitting element. In embodiments, the pixel circuit may include thin film transistors and capacitors. The pixels PX shown in FIG. 2 and FIG. 3 may be understood as indicating a light emitting area in which light from the light emitting element is outputted.

In embodiments, each of the plurality of pixels PX may be connected to at least one scan line and data line. When a scan signal is applied from the scan line, each of the plurality of pixels PX may receive a data voltage of the data line, and may emit light by supplying a driving current to the light emitting element according to the applied data voltage.

In some embodiments, one of the plurality of pixels PX may include a plurality of sub-pixels. For example, one of the pixels PX may include three sub-pixels, each of which may have a planar shape of a rectangular, square or rhombic shape. In addition, the plurality of sub-pixels may be arranged in a line in one direction (for example, the first direction D1), but the present disclosure is not limited thereto.

Each of the plurality of sub-pixels may include a light emitting element configured to emit light. The light emitting element may be provided in various forms. For example, the light emitting element may be an inorganic light emitting element including an inorganic material. In some embodiments, the light emitting element may be an organic light emitting diode (OLED).

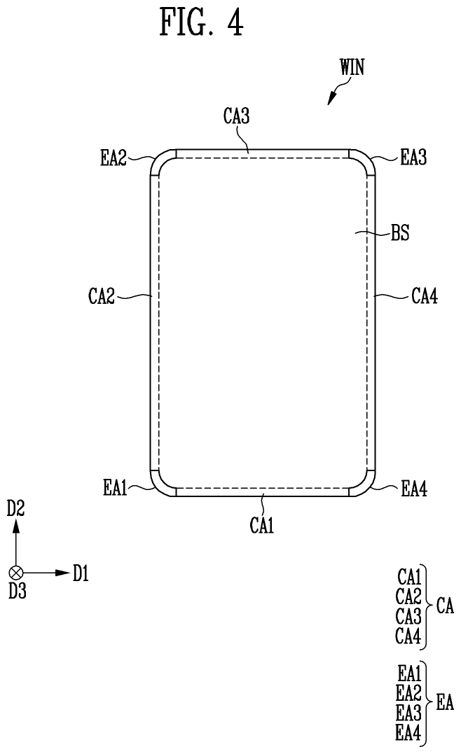

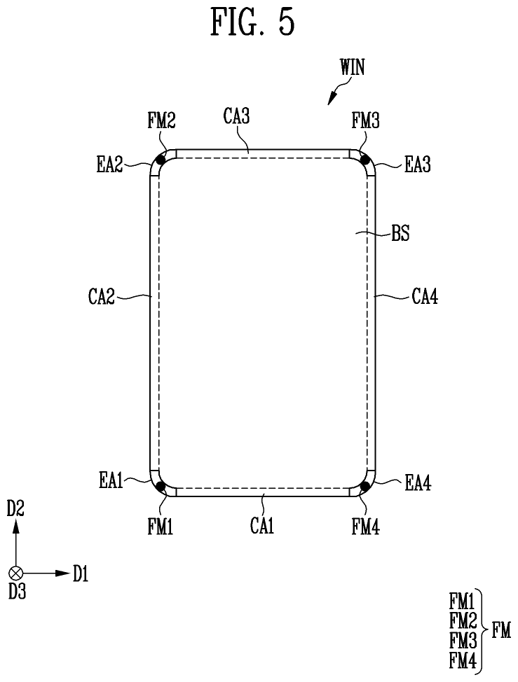

FIG. 4 illustrates a top plan view of an example of a window WIN shown in FIG. 2. FIG. 5 illustrates a top plan view of an example in which a filling member FM is disposed on a window WIN shown in FIG. 2.

In FIG. 4 and FIG. 5, a back surface of the window WIN is shown when the window WIN is viewed in the third direction D3.

Referring to FIG. 4, the window WIN may include a back area BS, curved areas CA including first to fourth curved areas CA1 to CA4, and edge areas EA including first to fourth edge areas EA1 to EA4. The curved areas CA may be bent from the back area BS in an opposite direction of the third direction D3.

Each of the edge areas EA may connect one of the curved areas CA and an adjacent one of the curved areas CA. For example, the first edge area EA1 may connect the first curved area CA1 and the second curved area CA2.

In some embodiments, each of the edge areas EA may be disposed at a corner of the window WIN. For example, the first edge area EA1 may be disposed at a corner of the window WIN between the first curved area CA1 and the second curved area CA2.

Each of the edge areas EA may have at least two curvatures. In addition, each of the edge areas EA may have a shape in which curved surfaces having different curvatures are continuously connected. For example, the first to fourth edge areas EA1 to EA4 may have two or more curvatures, and each thereof may have a different curvature.

Referring to FIG. 5, the window WIN may include filling members FM. For example, the window WIN may include first to fourth filling members FM1 to FM4 disposed on the first to fourth edge areas EA1 to EA4.

The filling members FM may include an optically clear resin (OCR). In some embodiments, the filling members FM may be disposed on the edge areas EA by an ink-jet method. For example, an inkjet head may be provided with a spray nozzle facing the back area BS of the window WIN. Thereafter, the optically clear resin (OCR) may be sprayed onto the edge areas EA through the spray nozzle. For example, optically clear adhesive resin (OCR) may be sprayed on the first edge area EA1, and then the inkjet head may sequentially move onto the second edge area EA2, the third edge area EA3, and the fourth edge area EA4 to spray the optically clear resin (OCR) on each of them. Accordingly, the first to fourth filling members FM1 to FM4 may be applied on each of the first to fourth edge areas EA1 to EA4. When the process is completed, the inkjet head may be removed from the window WIN.

The filling members FM may be cured before the display module DM and the window WIN are combined. In some embodiments, the filling members FM may be cured by light irradiated to each of the filling members FM. For example, ultraviolet (UV) rays may be sequentially irradiated to the first to fourth filling members FM1 to FM4 applied by the inkjet, and the first to fourth filling members FM1 to FM4 may be cured. Accordingly, a range in which the first to fourth filling members FM1 to FM4 are disposed may be controlled.

If the filling members are not cured, they may flow in the first direction D1 and/or the second direction D2 on the window, and the range in which the filling members are disposed may not be controlled.

On the other hand, according to the embodiment of the present disclosure, the fluidity of the cured filling members FM may be relatively controlled compared to the non-cured filling members. Accordingly, when the window WIN and the display module DM are combined, excessive spreading of the filling members FM in the first direction D1 and/or the second direction D2 may be prevented, and the filling members FM may be disposed within a desired range on the edge areas EA. As described above, as the filling members FM are cured before the window WIN and the display module DM are combined, the manufacturing process of the display device DD may be smoothly performed.

In some embodiments, the filling members FM may be semi-cured, and thus, a fine position movement between the window WIN and the adhesive layer AD may be possible. For example, compared to fully cured filling members, the semi-cured filling members FM may have relatively weak adherence. Accordingly, during the process of combining the display module DM and the window WIN, the semi-cured filling members FM may allow slight movement between the window WIN and the adhesive layer AD. Accordingly, precise alignment between the display module DM and the window WIN may be possible.

A refractive index of the filling members FM may be substantially the same as a refractive index of the adhesive layer AD (see FIG. 2). Accordingly, after the window WIN and the display module DM are combined, unintended refraction of the image displayed by the display module DM may be prevented.

If the refractive index of the filling members disposed on the window is different from the refractive index of the adhesive layer, the light of the image displayed by the display module may be refracted when passing between the adhesive layer and the filling members. Accordingly, the image displayed by the display module may be unintentionally refracted, and the visibility of the image provided by the display device may be deteriorated.

On the other hand, according to the embodiment of the present disclosure, the refractive index of the filling members FM may be substantially the same as the refractive index of the adhesive layer AD, and thus, when the light of the image displayed by the display module DM passes through the filling members FM, it may not be refracted. Accordingly, the display device DD may provide an image with improved visibility.

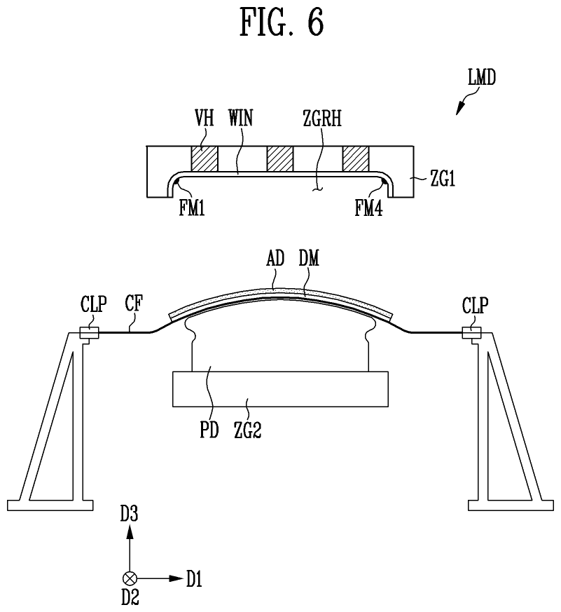

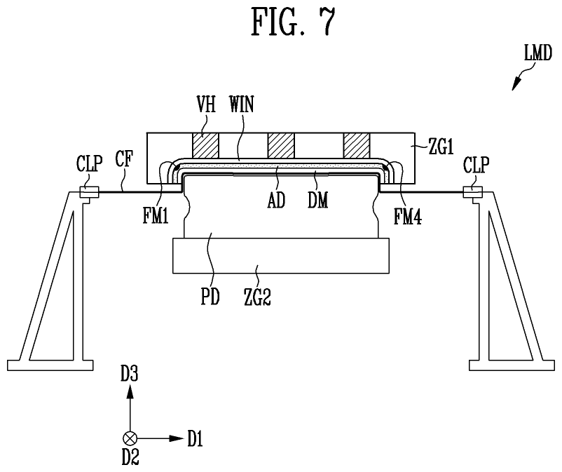

FIG. 6 and FIG. 7 illustrate some of a manufacturing method of a display device according to an embodiment of the present disclosure.

FIG. 6 and FIG. 7 illustrate a process in which the display module DM and the window WIN are combined by a lamination device LMD according to an embodiment, but the combining method is not limited thereto.

Referring to FIG. 6, the lamination device LMD may include a first jig ZG1 (or an upper jig), a pad PD (or a pressure pad), clamps CLP, and a second jig ZG2.

The first jig ZG1 may include a receiving groove ZGRH. The first jig ZG1 may include the receiving groove ZGRH defined by a bottom surface and a plurality of side surfaces that are bent and extended from the bottom surface. In some embodiments, a shape of a portion of the receiving groove ZGRH may have a shape corresponding to the shape of the window WIN.

The first jig ZG1 may include a plurality of vacuum holes VH, and accordingly, the window WIN may be fixed to the receiving groove ZGRH. For example, the vacuum holes VH suck in air between the receiving groove ZGRH and the window WIN, and the window WIN may be fixed to the receiving groove ZGRH through the lowered pressure.

The first jig ZG1 may be moved toward the second jig ZG2, or may be moved in a direction away from the second jig ZG2. For example, the first jig ZG1 may be moved along a direction parallel to the third direction D3.

The pad PD may be disposed below the first jig ZG1. The pad PD may be made of an elastic material. For example, the pad PD may include a material whose shape is easily changed by pressure. In some embodiments, the pad PD may include silicon.

In some embodiments, the adhesive layer AD may be combined with the display module DM by a roller. For example, the adhesive layer AD may be disposed on the upper surface of the display module DM on which the pixels PX (see FIG. 2) are arranged, and the adhesive layer AD may be combined with the upper surface of the display module DM by a roller.

The display module DM with which the adhesive layer AD is combined may be disposed on a carrier film CF. For example, the display module DM with which the adhesive layer AD is combined may be attached to the carrier film CF.

The clamps CLP may be arranged to be spaced apart from each other in the first direction D1. The clamps CLP may clamp the carrier film CF to which the display module DM is attached. That is, the display module DM is not directly fixed to the clamps CLP, but may be indirectly fixed to the clamps CLP through the carrier film CF. Accordingly, damage due to the clamping operation of the clamps CLP may not occur in the display module DM.

The clamps CLP may be moved in a direction close to each other or away from each other. For example, each of the clamps CLP may be moved in a direction parallel to the first direction D1.

The second jig ZG2 may be disposed under the pad PD. The second jig ZG2 may move the pad PD toward the first jig ZG1 or move it in a direction away from the first jig ZG1. For example, the second jig ZG2 may be moved along a direction parallel to the third direction D3 until the window WIN and the adhesive layer AD contact.

Referring to FIG. 7, the window WIN and the display module DM may be combined by the lamination device LMD. For example, the first jig ZG1 descends, the second jig ZG2 ascends, or the first jig ZG1 and the second jig ZG2 descend and ascend, so that they may approach each other. Hereinafter, for convenience of description, an example in which the first jig ZG1 is fixed and the second jig ZG2 ascends will be described.

As the second jig ZG2 ascends, the adhesive layer AD disposed on the display module DM may contact the window WIN. In this case, the carrier film CF, the display module DM, and the adhesive layer AD may be bent. For example, the display module DM may be bent in the third direction D3. After the display module DM is bent, the pad PD and the second jig ZG2 may be further moved in a direction toward the first jig ZG1. The direction toward the first jig ZG1 may be a direction parallel to the third direction D3. As the second jig ZG2 ascends, the contact areas between the window WIN and the display module DM and the adhesive layer AD may increase toward each other. For example, the contact area between the window WIN and the adhesive layer AD may increase toward the first direction D1 and toward an opposite direction of the first direction D1. Accordingly, the window WIN and the display module DM may be gradually adhered from the center toward both sides, and the window WIN and the display module DM may be combined through the adhesive layer AD.

According to the embodiment of the present disclosure, when the window WIN and the display module DM are combined, the filling members FM may compensate for a space that may exist between the window WIN and the adhesive layer AD. For example, when the window WIN and the display module DM are combined, spaces that may exist between the first to fourth edge areas EA1 to EA4 and the adhesive layer AD may be filled with the first to fourth members FM1 to FM4.

If the filling members are not disposed on curved portions having two or more curvatures, air bubbles may occur between the curved portions and the adhesive layer. For example, when the display module DM and the window WIN are combined, air bubbles may be formed between the edge areas EA and the adhesive layer AD.

A volume of the filling members FM may be larger than a volume of the air bubbles that may be formed between the edge areas EA and the adhesive layer AD when the display module DM and window WIN are combined. In some embodiments, the volume of the filling members FM may be 100 times or more than the volume of the air bubbles formed between the edge areas EA and the adhesive layer AD. As the volume of the filling members FM is significantly larger than the volume of the air bubbles, the risk of air bubbles occurring between the window WIN and the adhesive layer AD may be relatively reduced.

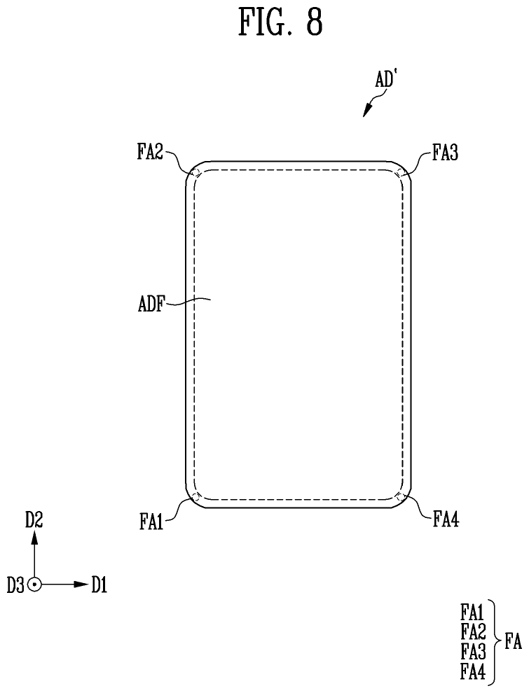

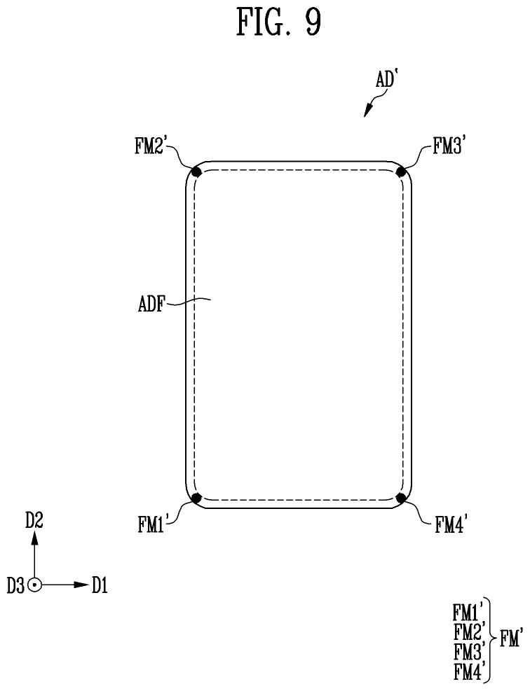

FIG. 8 illustrates a top plan view of another example of an adhesive layer AD′ similar to the adhesive layer AD shown in FIG. 2. FIG. 9 illustrates a top plan view of another example in which a filling member FM′ is disposed on the adhesive layer AD′ shown in FIG. 8.

In FIG. 8 and FIG. 9, an upper surface of an adhesive layer AD′ is shown when the adhesive layer AD′ is viewed in a direction opposite to the third direction D3.

Referring to FIG. 8, the adhesive layer AD′ may include an adhesive front area ADF and filling areas FA including first to fourth filling areas FA1 to FA4.

The adhesive front area ADF of the adhesive layer AD′ may correspond to the back area BS (see FIG. 4) of the window WIN. For example, the adhesive front area ADF of the adhesive layer AD′ may be disposed to overlap the back area BS of the window WIN.

The adhesive front area ADF of the adhesive layer AD′ may be substantially parallel to a plane defined by the first direction D1 and the second direction D2.

The filling areas FA may be respectively disposed at corners of the adhesive layer AD′. For example, the first to fourth filling areas FA1 to FA4 are disposed on the outside of the adhesive front area ADF, and each of the first to fourth filling areas FA1 to FA4 may be disposed at the corner of the adhesive layer AD′.

The filling areas FA may correspond to the edge areas EA (see FIG. 4) of the window WIN. For example, the first to fourth filling areas FA1 to FA4 may be disposed to overlap the first to fourth edge areas EA1 to EA4, respectively.

Referring to FIG. 9, the adhesive layer AD′ may include filling members FM′ including first to fourth filling members FM1′ to FM4′. For example, the adhesive layer AD′ may include the first to fourth filling members FM1′ to FM4′ disposed on the first to fourth filling areas FA1 to FA4.

The filling members FM′ of FIG. 9 may be described similarly to the filling members FM of FIG. 5. Hereinafter, redundant descriptions will be simplified or omitted.

The filling members FM′ may include an optically clear resin (OCR). In some embodiments, the filling members FM′ may be disposed on the filling areas FA by an ink-jet method, as described with reference to FIG. 5.

The filling members FM′ may be cured before the display module DM and the window WIN are combined. For example, before the display module DM and the window WIN are combined through the adhesive layer AD′, the filling members FM′ may be cured. In some embodiments, the filling members FM′ may be cured by light (for example, ultraviolet rays) irradiated to each of the filling member FM′.

According to the embodiment of the present disclosure, the fluidity of the cured filling members FM′ may be relatively controlled compared to the non-cured filling members. Accordingly, when the window WIN and the display module DM are combined, excessive spreading of the filling members FM′ in the first direction D1 and/or the second direction D2 may be prevented, and the filling members FM′ may be disposed within a desired range on the filling areas FA. As described above, as the filling members FM′ are cured before the window WIN and the display module DM are combined, the manufacturing process of the display device DD may be smoothly performed.

In some embodiments, the filling members FM′ may be semi-cured, and thus, a fine position movement between the window WIN and the adhesive layer AD′ may be possible. For example, during the process of for example the display module DM and the window WIN, the semi-cured filling members FM′ may allow slight movement between the window WIN and the adhesive layer AD′. Accordingly, precise alignment between the display module DM and the window WIN may be possible.

A refractive index of the filling members FM′ may be substantially the same as a refractive index of the adhesive layer AD′. Accordingly, after the window WIN and the display module DM are combined, unintentional refraction of the image displayed by the display module DM may be prevented, and the display device DD may provide an image with improved visibility.

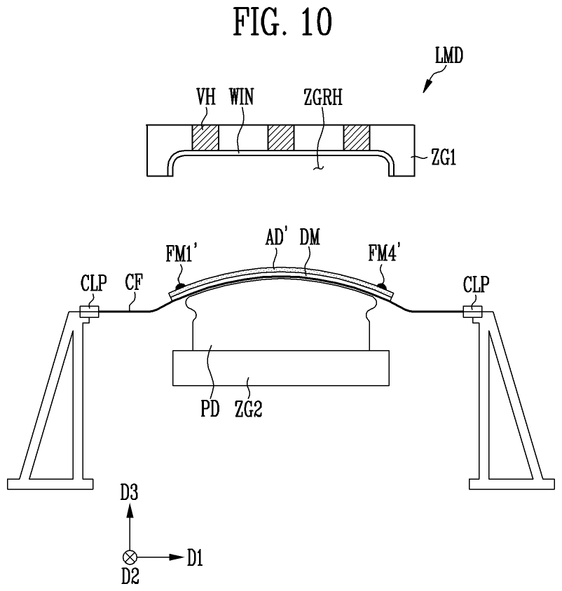

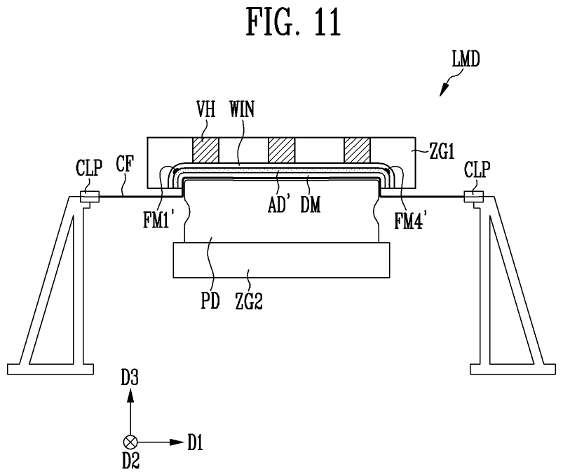

FIG. 10 and FIG. 11 illustrate some of a manufacturing method of a display device according to an embodiment of the present disclosure. The lamination device LMD of FIG. 10 may be described similarly to the lamination device LMD of FIG. 6, and redundant descriptions will be omitted.

In some embodiments, the adhesive layer AD′ may be combined with the display module DM by a roller. For example, the adhesive layer AD′ may be combined with the upper surface of the display module DM by a roller. Thereafter, the filling members FM′ may be disposed on the adhesive layer AD′. For example, the first filling member FM1′ and the fourth filling member FM4′ may be disposed on the first filling area FA1 and the fourth filling area FA4 of the adhesive layer AD′, respectively.

The display module DM to which the adhesive layer AD′ is combined may be disposed on a carrier film CF. For example, the display module DM to which the adhesive layer AD′ is combined may be attached to the carrier film CF.

Referring to FIG. 10 and FIG. 11, the window WIN and the display module DM may be combined by the lamination device LMD. The method by which the display module DM and the window WIN of FIG. 10 and FIG. 11 are combined may be described similarly to FIG. 6 and FIG. 7.

In some embodiments, as the second jig ZG2 ascends, the adhesive layer AD′ disposed on the display module DM may contact the window WIN.

In this case, the carrier film CF, the display module DM, and the adhesive layer AD′ may be bent. After the display module DM is bent, the pad PD and the second jig ZG2 may be further moved in a direction toward the first jig ZG1. As the second jig ZG2 ascends, the contact areas between the window WIN and the display module DM and the adhesive layer AD′ may increase toward each other. Accordingly, the window WIN and the display module DM may be gradually adhered from the center toward both sides, and the window WIN and the display module DM may be combined through the adhesive layer AD′.

According to the embodiment of the present disclosure, when the window WIN and the display module DM are combined, the filling members FM′ may compensate for a space that may exist between the window WIN and the adhesive layer AD′. For example, the spaces that may exist between the first to fourth edge areas EA1 to EA4 and the first to fourth filling areas FA1 to FA4 may be filled with the first to fourth filling members FM1′ to FM4′.

If the filling members are not disposed on curved portions having two or more curvatures, air bubbles may occur between the curved portions and the adhesive layer. For example, when the display module DM and the window WIN are combined, air bubbles may be formed between the edge areas EA and the adhesive layer AD′.

A volume of the filling members FM′ may be larger than a volume of the air bubbles that may be formed between the edge areas EA and the adhesive layer AD′ when the display module DM and window WIN are combined. In some embodiments, the volume of the filling members FM′ may be 100 times or more than the volume of the air bubbles formed between the edge areas EA and the adhesive layer AD′. As the volume of the filling members FM′ is significantly larger than the volume of the air bubbles, the risk of air bubbles occurring between the window WIN and the adhesive layer AD′ may be relatively reduced.

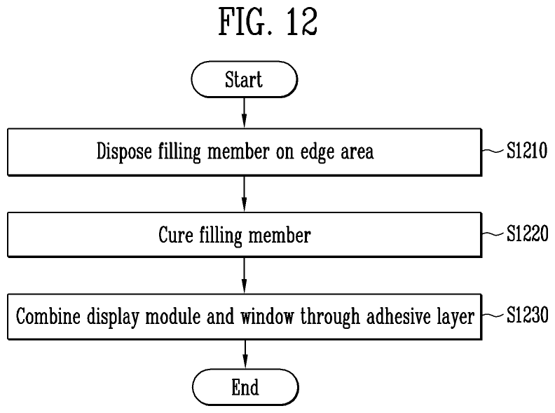

FIG. 12 illustrates a flowchart of a manufacturing method of a display device according to an embodiment of the present disclosure.

Referring to FIG. 12, a manufacturing method of the display device DD according to the embodiment may include disposing a filling member on an edge area (operation S1210), curing the filling member (operation S1220), and combining a display module and a window through an adhesive layer (operation S1230).

Referring to FIGS. 4, 5 and 12, in operation S1210, the filling members FM may be disposed on the edge areas EA. In some embodiments, operation S1210 may be performed by an ink-jet method, but is not limited thereto.

In operation S1220, the filling members FM may be cured before the display module DM and the window WIN are combined. The filling members FM may be cured by irradiating light (for example, ultraviolet rays) to the filling members FM. In some embodiments, light may be radiated to the filling members FM to semi-cure them.

In operation S1230, the display module DM and the window WIN may be combined through the adhesive layer AD. The adhesive layer AD may be disposed on the display module DM, and then the display module DM and the window WIN may be combined.

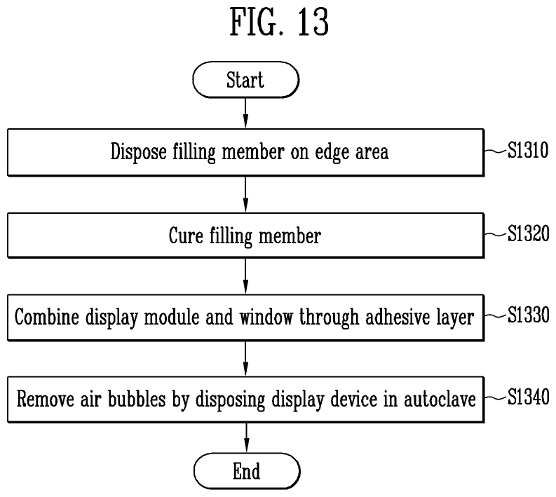

FIG. 13 illustrates a flowchart of a manufacturing method of a display device according to an embodiment of the present disclosure.

Referring to FIG. 13, a manufacturing method of the display device DD according to the embodiment may include disposing a filling member on an edge area (operation S1310), curing the filling member (operation S1320), combining a display module and a window through an adhesive layer (operation S1330), and removing air bubbles by disposing a display device in an autoclave (operation S1340).

Each of operations S1310, S1320, and S1330 of FIG. 13 may be described similarly to each of operations S1210, S1220, and S1230 of FIG. 12, so redundant descriptions will be omitted.

Referring to FIG. 7 and FIG. 13, air bubbles may be removed by disposing the display device DD in the autoclave. For example, after operation S1330, the display device DD in which the display module DM and the window WIN are combined may be disposed in the autoclave. Then, air bubbles existing between the display module DM and the window WIN may be removed.

In this case, the air bubbles between the display module DM and the window WIN may be relatively small due to the filling members FM. Accordingly, the time for the display device DD to be disposed in the autoclave may be shortened, and the manufacturing process of the display device DD may be quickly performed.

Although certain embodiments and implementations have been described herein, other embodiments and modifications will be apparent from this description. Accordingly, the inventive concept is not limited to the embodiments, but rather to the broader scope of the presented claims and various obvious modifications and equivalent arrangements.

What is claimed is:

1. A display device comprising:
a display module including a display area;
a window comprising:
a front area;
curved areas bent with a curvature from the front area; and
an edge area connecting one of the curved areas to another of the curved areas;
an adhesive layer disposed between the display module and the window; and
a filling member disposed on the edge area, wherein,
a volume of the filling member is greater than a volume of air bubbles formed between the edge area and the adhesive layer when the display module and the window are combined.

2. The display device of claim 1, wherein,
the volume of the filling member is 100 times or more than the volume of the air bubbles.

3. The display device of claim 1, wherein,
the filling member is cured before the window and the display module are combined.

4. The display device of claim 1, wherein,
a refractive index of the filling member is substantially the same as a refractive index of the adhesive layer.

5. The display device of claim 4, wherein,
the filling member includes an optically clear resin.

6. The display device of claim 4, wherein,
the adhesive layer includes an optically clear adhesive.

7. A display device comprising:
a display module including a display area;
a window comprising:
a front area;
curved areas bent with a curvature from the front area; and
an edge area connecting one of the curved areas to another of the curved areas; and
an adhesive layer disposed between the display module and the window, the adhesive layer including a filling area in contact with the edge area; and
a filling member disposed on the filling area when the display module and the window are combined, wherein,
a volume of the filling member is greater than a volume of air bubbles formed between the edge area and the adhesive layer when the display module and the window are combined.

8. The display device of claim 7, wherein,
the volume of the filling member is 100 times or more than the volume of the air bubbles.

9. The display device of claim 7, wherein,
the filling member is cured before the window and the display module are combined.

10. The display device of claim 7, wherein,
a refractive index of the filling member is substantially the same as a refractive index of the adhesive layer.

11. The display device of claim 10, wherein,
the filling member includes an optically clear resin, and
the adhesive layer includes an optically clear adhesive.

12. A manufacturing method of a display device including a display module and a window, comprising:
disposing a filling member on an edge area that connects one of curved areas included in the window to another of the curved areas;
curing the filling member; and
combining the display module and the window through an adhesive layer, wherein,
a volume of the filling member is greater than a volume of air bubbles formed between the edge area and the adhesive layer when the display module and the window are combined.

13. The manufacturing method of claim 12, further comprising:
removing the air bubbles by disposing the display device in an autoclave.

14. The manufacturing method of claim 12, wherein,
the volume of the filling member is 100 times or more than the volume of the air bubbles.

15. The manufacturing method of claim 12, wherein,
the filling member is cured before the window and the display module are combined.

16. The manufacturing method of claim 12, wherein,
a refractive index of the filling member is substantially the same as a refractive index of the adhesive layer.

17. The manufacturing method of claim 16, wherein,
the filling member includes an optically clear resin, and
the adhesive layer includes an optically clear adhesive.

18. The manufacturing method of claim 12, wherein,
the filling member is disposed on the edge area by an ink-jet method.
